(19) United States
(12) Patent Application Publication
(10) Pub. No.: US 2026/0150590 A1
(43) Pub. Date: May 28, 2026

(54) RESISTIVE RANDOM ACCESS MEMORIES (RRAM) AND METHODS OF FABRICATING THE SAME

(71) Applicant: Tokyo Electron Limited, Tokyo (JP)

(72) Inventors: Devi KOTY, Hopewell Junction, NY (US); Takashi ANDO, Yorktown Heights, NY (US); Hiroyuki MIYAZOE, Yorktown Heights, NY (US); Qingyun YANG, Hopewell Junction, NY (US); Takaaki TSUNOMURA, Tokyo (JP); Steven CONSIGLIO, Albany, NY (US); Kenichi IMAKITA, Albany, NY (US)

(73) Assignee: Tokyo Electron Limited, Tokyo (JP)

(21) Appl. No.: 18/956,597

(22) Filed: Nov. 22, 2024

(51) Int. Cl. H10N 70/20; H10B 63/00; H10N 70/00

(52) U.S. Cl. CPC H10N 70/24; H10B 63/00; H10N 70/011; H10N 70/841; H10N 70/8833

(57) ABSTRACT

Aspects of the present disclosure provide a method of fabricating a resistive random access memory (RRAM). For example, the method can include providing a substrate, forming a first electrode on the substrate, and forming a first metal oxide layer on the first electrode. The first metal oxide layer can act as a sink or reservoir of oxygen atoms that interact with a current conducting filament. The method can further include forming a second metal oxide layer on the first metal oxide layer. The second metal oxide layer can be configured to form conduction paths. The method can further include forming a second electrode on the second metal oxide layer. In an embodiment, the first metal oxide layer can be formed on a portion of the first electrode.

### FIELD OF THE INVENTION

The present disclosure relates to random access memories (RAMs), and, in particular, to resistive random access memories (RRAMs) and methods of fabricating the same.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Recently, in order to follow the trend of compact size and high performance of electronic devices, semiconductor memories that are capable of storing data in various electronic devices are required. Examples of the memories may include static random access memory (SRAM), dynamic random access memory (DRAM), resistive random access memory (RRAM), etc. A RRAM can store data by using the characteristic that switching between different resistance states, e.g., high resistance state (HRS) and low resistance state (LRS), is controlled based on a forming (or writing) voltage or current applied thereto.

### SUMMARY

Aspects of the present disclosure provide a method of fabricating a resistive random access memory (RRAM). For example, the method can include providing a substrate, forming a first electrode on the substrate, and forming a first metal oxide layer on the first electrode. The first metal oxide layer can act as a sink or reservoir of oxygen atoms that interact with a current conducting filament. The method can further include forming a second metal oxide layer on the first metal oxide layer. The second metal oxide layer can be configured to form conduction paths. The method can further include forming a second electrode on the second metal oxide layer. In an embodiment, the first metal oxide layer can be formed on a portion of the first electrode.

In an embodiment, the second metal oxide layer can include hafnium oxide (HfOₓ). For example, x can be greater than 1.0±0.1 and less than 2.0±0.1. In another embodiment, the first metal oxide layer can include tungsten oxide (WO_{y}). For example, y can be greater than 1.0±0.1 and less than 3.0±0.1. In some embodiments, the first metal oxide layer can include WO_{y}, the second metal oxide layer can include HfOₓ, x can be greater than 1.0±0.1 and less than 2.0±0.1, and y can be greater than 1.0±0.1 and less than 3.0±0.1.

In an embodiment, the method can further include forming an electrical contact on the second electrode. For example, the electrical contact can be formed on a portion of the second electrode. In another embodiment, the method can further include forming an additional electrical contact that electrically connects the first electrode through a via that penetrates the first metal oxide layer.

Aspects of the present disclosure also provide an RRAM. For example, the RRAM can include a first electrode and a first metal oxide layer that is formed on the first electrode. The first metal oxide layer can act as a sink or reservoir of oxygen atoms that interact with a current conducting filament. The RRAM can further include a second metal oxide layer that is formed on the first metal oxide layer. The second metal oxide layer can be configured to form conduction paths. The RRAM can further include a second electrode that is formed on the second metal oxide layer. In some embodiments, the first metal oxide layer can include tungsten oxide (WO_{y}), and the second metal oxide layer can include hafnium oxide (HfOₓ) that is independent of thickness and composition of the WO_{y}. In an embodiment, the first metal oxide layer can have a capability of either absorbing or releasing oxygen atoms interacting with oxygen vacancy based current conducting filaments in the second metal oxide layer. In another embodiment, the second metal oxide layer can have a capability of forming current conducting filament(s) during an electro-forming process, performed after the device fabrication. This bi-layer stack enables fine tuning of filament configuration via electrical bias on the electrodes and thereby adjustment of device conductance in an analog fashion.

In an embodiment, x can be greater than 1.0±0.1 and less than 2.0±0.1. In another embodiment, y can be greater than 1.0±0.1 and less than 3.0±0.1. In some embodiments, x can be greater than 1.0±0.1 and less than 2.0±0.1, and y can be greater than 1.0±0.1 and less than 3.0±0.1.

In an embodiment, the first metal oxide layer can be formed on a portion of the first electrode. In some embodiments, the RRAM can further include an electrical contact formed on the second electrode. For example, the electrical contact can be formed on a portion of the second electrode. As another example, the RRAM can further include an additional electrical contact that electrically connects the first electrode through a via that penetrates the first metal oxide layer.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a resistive random access memory (RRAM);

FIG. 2 is a flow chart of a method of fabricating the RRAM of FIG. 1;

FIG. 3 shows an exemplary RRAM according to some embodiments of the present disclosure; and

FIG. 4 is a flow chart of an exemplary method of fabricating the RRAM of FIG. 3 according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

A resistive random access memory (RRAM) includes a resistive switching memory cell that has a metal-insulator-metal (MIM) structure and involves frequent transitions between a high resistance state (HRS) (or OFF state generally referred to as logic value “0”) and a low resistance state (LRS) (or ON state generally referred to as logic value “1”). When a forming voltage is applied to the RRAM, an electroforming process occurs due to the soft breakdown of the MIM structure, conduction paths (i.e., current conducting filaments) are thus grew and formed in the insulator, and the RRAM is switched from the HRS to the LRS. When an erase (or reset) voltage is applied, the RRAM can be switched from the LRS to the HRS. The insulator (or known as a resistance switching layer), which exhibits the resistance switching characteristic, can include metal oxide such as hafnium oxide (HfOₓ), titanium oxide (TiOₓ), tantalum oxide (TaOₓ), nickel oxide (NiO), zinc oxide (ZnO), zinc titanate (Zn₂TiO₄), manganese oxide (MnO₂), aluminum oxide (AlO), etc, which can afford the RRAM with lower forming voltage and increased Iₒₙ/I_{off} ratio.

RRAM can be considered as a promising technology for electronic synapse devices or memristor for neuromorphic computing as well as high-density and high-speed non-volatile memory applications. In neuromorphic computing applications, a resistive memory device, e.g., RRAM, can be used as a connection (or synapse) between a pre-neuron and a post-neuron in an artificial neural network (ANN), representing the connection weight in the form of device resistance. The readout of an RRAM can be carried out according to a multiply-accumulate operation, during which data stored (e.g., taken as a weight of a neuron) and a signal (e.g., a current) input to the RRAM impact the readout. For example, the signal input to the RRAM (e.g., a pre-neuron) is multiplied by the data stored in the RRAM to form the readout, which can be input to a post-neuron. Multiple pre-neurons and post-neurons can be connected through a crossbar array (e.g., M×N) of RRAMs, which naturally expresses a fully-connected neural network.

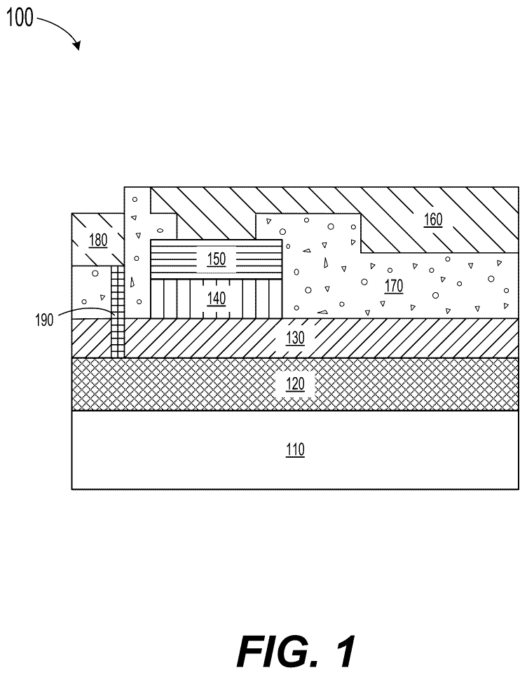

FIG. 1 shows an RRAM 100. The RRAM 100 can include a bilayer insulator structure that is sandwiched and electrically connected between two electrodes. The bilayer insulator structure includes a first metal oxide layer that is configured to form conduction paths and a second metal oxide layer that acts a sink or reservoir of oxygen atoms that interact with a current conducting filament. As shown, the RRAM 100 can include a substrate 110. The substrate 110 can be a silicon (Si) substrate, a germanium (Ge) substrate, etc., which can be doped (e.g., highly doped) with dopants.

The RRAM 100 can further include a first (or bottom) electrode 120 that is formed on the substrate 110. A variety of materials have been used as an electrode for an RRAM, e.g., the bottom electrode 120 of the RRAM 100. These electrode materials can be categorized into five groups based on their composition, including elementary substance electrodes (e.g., aluminum (AL), titanium (Ti), copper (Cu), graphene, carbon nanotubes, silver (Ag), tungsten (W), platinum (Pt), etc.), silicon-based electrodes (e.g., p-type silicon, n-type silicon, etc.), alloy electrodes (e.g., Cu—Ti, Cu-tellurium (Te), Pt—Al, etc.), oxide electrodes (e.g., Al-doped zinc oxide (ZnO), indium tin oxide (ITO), etc.), and nitride-based electrodes (e.g., TiN, TaN, etc.). The RRAM 100 can be grounded via the bottom electrode 120.

The RRAM 100 can further include a first metal oxide layer (e.g., a hafnium oxide (HfOₓ) layer) 130 that is configured to form conduction paths. As shown, the HfOₓ layer 130 is formed on and being in direct contact with the bottom electrode 120. The HfOₓ layer 130 can be amorphous. The HfOₓ layer 130 can be a sub-stoichiometric layer. For example, x can be greater than 1.0±0.1 and less than 2.0±0.1.

The RRAM 100 can further include a second metal (e.g., W, Ti, etc.) oxide (MO_{y}) layer 140 that acts as a sink or reservoir of oxygen atoms that interact with a current conducting filament. As shown, the MO_{y} layer 140 is formed on a portion of the HfOₓ layer 130. The MO_{y} layer 140 can have a polycrystalline structure, which allows the MO_{y} layer 140 to have its resistivity vary up to four orders of magnitude, e.g., between 10⁻² to 10⁺² Ω-cm. The MO_{y} layer 140 can also be a sub-stoichiometric layer. For example, y can be greater than 1.0±0.1 and less than 3.0±0.1. The HfOₓ layer 130 and the MO_{y} layer 140 constitute the bilayer insulator structure of the RRAM 100, in which x may be greater than 1.0±0.1 and less than 2.0±0.1 and y may be greater than 1.0±0.1 and less than 3.0±0.1. The MO_{y} layer 140 acts as a sink or reservoir of oxygen atoms that interact with a current conducting filament, and oxygen exchanges can be evoked between the MO_{y} layer 140 and current conducting filaments formed in the HfOₓ layer 130 when a forming voltage is applied to the RRAM 100. The current conducting filaments are grown in the HfOₓ layer 130 as channels having a very small diameter of the order of nanometers.

The RRAM 100 can further include a second (or top) electrode 150 that is formed on the MO_{y} layer 140. The top electrode 150 can also include elementary substance electrode, silicon-based electrode, alloy electrode, oxide electrode, and nitride-based electrode. Therefore, the bottom electrode 120 and the top electrode 150 are in direct contact with the bilayer insulator structure on opposite sides thereof.

The RRAM 100 can further include an electrical contact 160 that is electrically connected to the top electrode 150. The electrical contact 160 may partially cover the top electrode 150. The RRAM 100 can further include an insulating layer 170 that covers and embeds the top electrode 150 to prevent the top electrode 150 from undesired oxidation. The insulating layer 170 can include silicon oxide (SiO₂), silicon nitride (SiN), etc. The RRAM 100 can further include an additional electrical contact 180 that partially covers and electrically connects the bottom electrode 120 through a via 190 that penetrates the HfOₓ layer 130 and the insulating layer 170.

The RRAM 100 can be fabricated as a nanoscale device. For example, the HfOₓ layer 130 can be between 1 nm and 10 nm in thickness, the MO_{y} layer 140 can be between 1 nm and 50 nm in thickness, and the bottom electrode 120 and the top electrode 150 each can be between 10 nm and 100 nm in thickness.

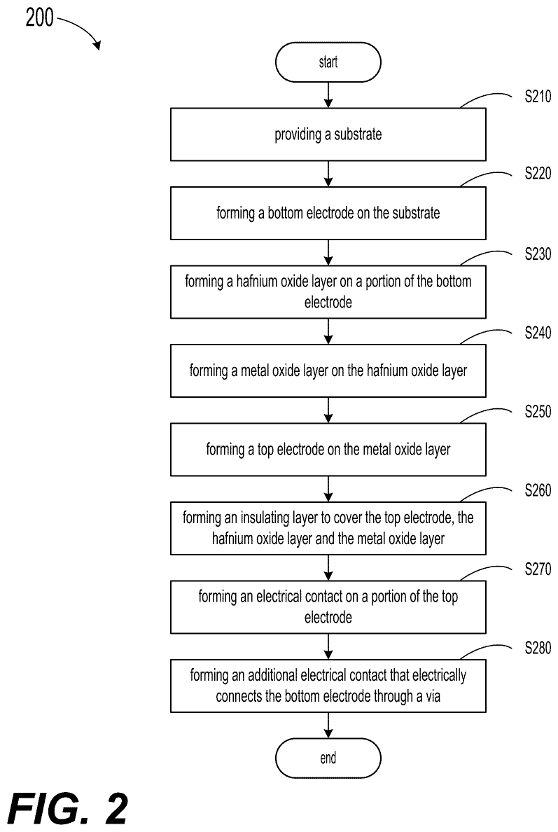

FIG. 2 is a flow chart of a method 200 of fabricating an RRAM, e.g., the RRAM 100. In various embodiments, some of the steps of the method 200 shown can be performed concurrently or in a different order than shown, can be substituted by other method steps, or can be omitted. Additional method steps can also be performed as desired. The method 200 can start with step S210, at which a substrate, e.g., the substrate 110, is provided. The method 200 can proceed to step S220.

At step S220, a first (or bottom) electrode, e.g., the bottom electrode 120, is formed on the substrate 110, for example, by atomic layer deposition (ALD). The method 200 can proceed to step S230.

At step S230, an HfOₓ layer, e.g., the HfOₓ layer 130, is formed on a portion of the bottom electrode 120 and being in electrical contact with the bottom electrode 120, for example, by ALD, pulse laser deposition (PLD), reactive sputtering, etc. In order to prevent the formed bottom electrode 120 from undesired oxidation, the HfOₓ layer 130 is formed immediately after the formation of the bottom electrode 120, without exposing the bottom electrode 120 to air. The method 200 can proceed to step S240.

At step S240, an MO_{y} layer, e.g., the MO_{y} layer 140, is formed on and being in electrical contact with the HfOₓ layer 130, for example, by ALD, PLD, reactive sputtering, etc., for oxygen exchanges to be evoked therebetween. For example, the MO_{y} layer 140 can be formed by sputtering tungsten (W), for example, in vacuum, to form a tungsten layer, oxidizing the tungsten layer under an oxygen (O₂) environment in an oven at a controlled temperature (e.g., at least 300° C. such as between 300° C. and 450° C., between 300° C. and 600° C., etc.) and a controlled time to form a polycrystalline monoclinic WO₃ layer, the thickness of which relates to the temperature and duration of the oxidation process, and reducing the WO₃ layer in an H₂+Ar (or N) gas to obtain the sub-stoichiometric MO_{y} layer 140, where y is less than 3, e.g., between 1.0±0.1 and less than 3.0±0.1. The method 200 can proceed to step S250.

At step S250, a second (or top) electrode, e.g., the top electrode 150, is formed on and being in electrical contact with the MO_{y} layer 140, for example, by sputtering. The method 200 can proceed to step S260.

At step S260, an insulating layer, e.g., the insulating layer 170, is formed, for example, by plasma-enhanced chemical vapor deposition (PECVD), to cover and embed the top electrode 150, the MO_{y} layer 140 and the HfOₓ layer 130. The method 200 can proceed to step S270.

At step S270, an electrical contact, e.g., the electrical contact 160, is formed, for example, by sputtering and patterned, on a portion of the top electrode 150. For example, a trench can be opened in the insulating layer 170 to uncover the portion of the top electrode 150, and a material for forming the electrical contact 160 can be inserted into the trench and reach the uncovered portion of the top electrode 150. Optionally, the method 200 can proceed to step S280.

At step S280, an additional electrical contact, e.g., the additional electrical contact 180, can be formed, for example, by sputtering and patterned, to partially cover and electrically connect the bottom electrode 120. For example, a via, e.g., the via 190, can be opened in the insulating layer 170 and the HfOₓ layer 130 to uncover a portion of the bottom electrode 120, and a material for forming the electrical contact 180 can be inserted into the via 190 and reach the uncovered portion of the bottom electrode 120.

Oxygen vacancies in the HfOₓ layer 130 are the building blocks of current conducting filaments. Therefore, the RRAM 100 need to be formed without introducing damages in a perimeter. And then, the RRAM 100 needs to be protected with an encapsulation layer to prevent oxygen penetrating during subsequent processes.

In operation, the HfOₓ layer 130 of the RRAM 100 is initially in the HRS; when a forming voltage (or a forming voltage pulse) is applied to the RRAM 100 at the top electrode 150, oxygen ions are driven by the forming voltage and leave the HfOₓ layer 130, and the equivalent positive oxygen vacancies left in the HfOₓ layer 130 form current conducting filaments, which in turn switch the HfOₓ layer 130 from the HRS to the LRS; and when an erase (or reset) voltage (or a reset voltage pulse) is applied, the oxygen ions return to the HfOₓ layer 130 and combine with the equivalent positive oxygen vacancies, which causes the current conducting filaments to disappear and the HfOₓ layer 130 to be switched from the LRS to the HRS.

In the RRAM 100, the MO_{y} layer 140 acts as a good oxygen sink or reservoir and exhibits suitable, non-volatile resistive switching characteristics. Compared to Ti/HfO₂ RRAM, the RRAM 100 based on a MO_{y}/HfOₓ bilayer insulator structure results in a more gradual HRS-to-LRS transition and in a more tunable HRS and LRS upon applying the programming voltage pulses. Moreover, no major drift<0.2% is observed for the different programmed states.

However, the forming voltage depends on the thickness of the MO_{y} layer 140 because the deposition process performed for the formation of the MO_{y} layer 140 also impacts the performance of the HfOₓ layer 130. For example, the HfOₓ layer 130 is also oxidized when the tungsten layer is oxidized. In general, the thinner the MOy layer 140 is, the lower the oxygen vacancy concentration in the HfOx layer 130, which affects the forming voltage and the device conductance of the bi-layer stack.

The present disclosure relates to a resistive random access memory (RRAM) and a method of fabricating the same, a forming voltage applied to the RRAM being independent from the thickness of a metal oxide layer (i.e., an MO_{y} layer) of the RRAM. In an embodiment, the RRAM can include an HfOₓ layer and an MO_{y} layer that is formed prior to the formation of the HfOₓ layer.

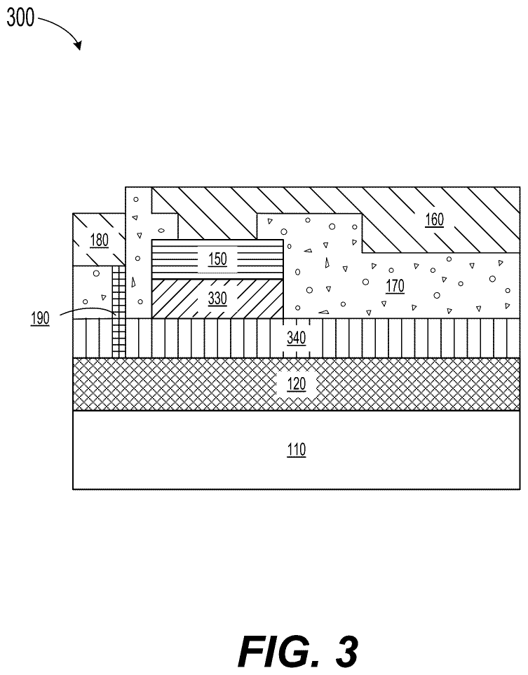

FIG. 3 shows an exemplary RRAM 300 according to some embodiments of the present disclosure. Similar to the RRAM 100 shown in FIG. 1, the RRAM 300 can also include a substrate (e.g., the substrate 110), a bottom electrode (e.g., the bottom electrode 120) that is formed on the substrate 110, a bilayer insulator structure (which is constituted by an MO_{y} layer 340 and an HfOₓ layer 330) that is formed on a portion of the bottom electrode 120, a top electrode (e.g., the top electrode 150) that is formed on the bilayer insulator structure, an electrical contact (e.g., the electrical contact 160) that is formed to cover (e.g., partially cover) the top electrode 150, an insulating layer (e.g., the insulating layer 170) that is formed to cover and embed the top electrode 150, and, optionally, an additional electrical contact (e.g., the electrical contact 180) that partially covers and electrically connects the bottom electrode 120 through a via (e.g., the 190) that penetrates the MO_{y} layer 340 and the insulating layer 170. Different from the RRAM 100, in which the HfOₓ layer 130 is formed between the MO_{y} layer 140 and the substrate 110, the RRAM 300 has the MO_{y} layer 340 formed between the HfOₓ layer 330 and the substrate 110.

In an embodiment, the HfOₓ layer 330 can be a sub-stoichiometric layer. For example, x can be greater than 1.0±0.1 and less than 2.0±0.1. In another embodiment, the MO_{y} layer 340 can have a polycrystalline structure, and also be a sub-stoichiometric layer. For example, y can be greater than 1.0±0.1 and less than 3.0±0.1.

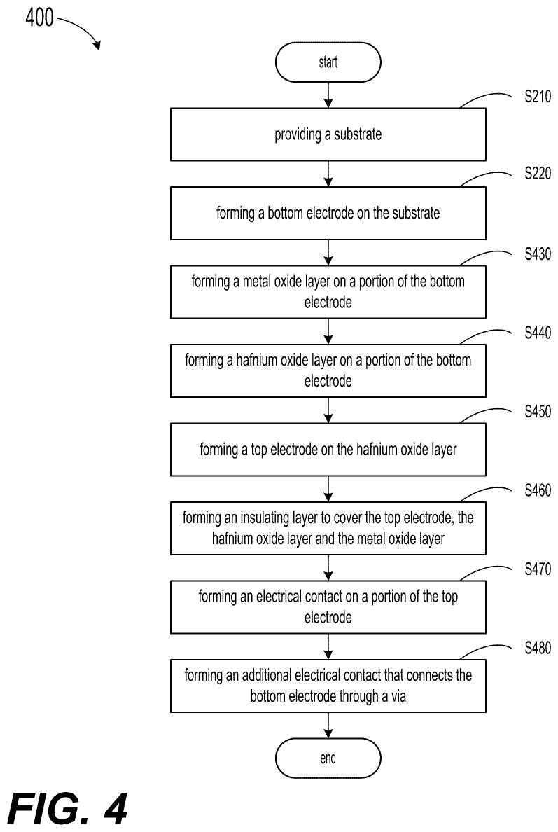

FIG. 4 is a flow chart of an exemplary method 400 of fabricating an RRAM, e.g., the RRAM 300, according to some embodiments of the present disclosure. In various embodiments, some of the steps of the method 400 shown can be performed concurrently or in a different order than shown, can be substituted by other method steps, or can be omitted. Additional method steps can also be performed as desired. The method 400 can also include steps S210 and S220 of the method 200. The method 400 can proceed to step S430.

At step S430, an MO_{y} layer, e.g., the MO_{y} layer 340, is formed on a portion of the bottom electrode 120 and being in electrical contact with the bottom electrode 120, for example, by ALD, PLD, reactive sputtering, etc. In order to prevent the formed bottom electrode 120 from undesired oxidation, the MO_{y} layer 340 is formed immediately after the formation of the bottom electrode 120, without exposing the bottom electrode 120 to air. For example, the MO_{y} layer 340 can be formed by sputtering tungsten (W), for example, in vacuum, to form a tungsten layer, oxidizing the tungsten layer under an oxygen (O₂) environment in an oven at a controlled temperature (e.g., at least 300° C. such as between 300° C. and 450° C., between 300° C. and 600° C., etc.) and a controlled time to form a polycrystalline monoclinic WO₃ layer, the thickness of which relates to the temperature and duration of the oxidation process, and reducing the WO₃ layer in an H₂+Ar (or N) gas to obtain the sub-stoichiometric MO_{y} layer 340, where y is less than 3, e.g., between 1.3±0.1 and less than 1.9±0.1. The method 400 can proceed to step S440.

At step S440, an HfOₓ layer, e.g., the HfOₓ layer 330, is formed on and being in electrical contact with the MO_{y} layer 340, for example, by ALD, PLD, reactive sputtering, etc., for oxygen exchanges to be evoked therebetween. The method 400 can proceed to step S450.

At step S450, a second (or top) electrode, e.g., the top electrode 150, is formed on and being in electrical contact with the HfOₓ layer 330, for example, by sputtering. The method 400 can proceed to step S460.

At step S460, an insulating layer, e.g., the insulating layer 170, is formed, for example, by PECVD, to cover and embed the top electrode 150, the HfOₓ layer 330 and the MO_{y} layer 340. The method 400 can proceed to step S470.

At step S470, an electrical contact, e.g., the electrical contact 160, is formed, for example, by sputtering and patterned, on a portion of the top electrode 150. For example, a trench can be opened in the insulating layer 170 to uncover the portion of the top electrode 150, and a material for forming the electrical contact 160 can be inserted into the trench and reach the uncovered portion of the top electrode 150. Optionally, the method 400 can proceed to step S480.

At step S480, an additional electrical contact, e.g., the additional electrical contact 180, can be formed, for example, by sputtering and patterned, to partially cover and electrically connect the bottom electrode 120. For example, a via, e.g., the via 190, can be opened in the insulating layer 170 and the MO_{y} layer 340 to uncover a portion of the bottom electrode 120, and a material for forming the electrical contact 180 can be inserted into the via 190 and reach the uncovered portion of the bottom electrode 120.

The RRAM 300 can also be fabricated as a nanoscale device. For example, the MO_{y} layer 340 can be between 1 nm and 50 nm in thickness, the HfOₓ layer 330 can be between 1 nm and 10 nm (e.g., 4 nm) in thickness, and the bottom electrode 120 and the top electrode 150 each can be between 10 nm and 100 nm (e.g., 20 nm) in thickness.

In the exemplary method 400, when the HfOₓ layer 330 is formed, the MO_{y} layer 340 is already formed on the bottom electrode 120, and the performance of HfOₓ layer 330 is not impacted by the deposition process performed for the formation of the MO_{y} layer 340. Therefore, the forming voltage of the RRAM 300 is independent from the thickness of the MO_{y} layer 340. The forming voltages for a left RRAM that includes 4 nm thickness of HfO and 7nm thickness of MO that is formed before the HfO and a right RRAM that includes 4 nm thickness of HfO and 20 nm thickness of MO that is formed before the HfO can be substantially equal, even though the MO of the right RRAM is almost three times thicker than the MO of the left RRAM.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of fabricating a resistive random access memory, comprising:
providing a substrate;
forming a first electrode on the substrate;
forming a first metal oxide layer on the first electrode, the first metal oxide layer acting as a sink or reservoir of oxygen atoms that interact with a current conducting filament;
forming a second metal oxide layer on the first metal oxide layer, the second metal oxide layer configured to form conduction paths; and
forming a second electrode on the second metal oxide layer.

2. The method of claim 1, wherein the second metal oxide layer includes hafnium oxide (HfOₓ).

3. The method of claim 2, where x is greater than 1.0±0.1 and less than 2.0±0.1.

4. The method of claim 1, wherein the first metal oxide layer includes tungsten oxide (WO_{y}).

5. The method of claim 4, where y is greater than 1.0±0.1 and less than 3.0±0.1.

6. The method of claim 1, wherein the first metal oxide layer includes WO_{y}, the second metal oxide layer includes HfOₓ, x is greater than 1.0±0.1 and less than 2.0±0.1, and y is greater than 1.0±0.1 and less than 3.0±0.1.

7. The method of claim 1, wherein the first metal oxide layer is formed on a portion of the first electrode.

8. The method of claim 1, further comprising:
forming an electrical contact on the second electrode.

9. The method of claim 8, wherein the electrical contact is formed on a portion of the second electrode.

10. The method of claim 8, further comprising:
forming an additional electrical contact that electrically connects the first electrode through a via that penetrates the first metal oxide layer.

11. A resistive random access memory (RRAM), comprising:
a first electrode;
a first metal oxide layer formed on the first electrode, the first metal oxide layer acting as a sink or reservoir of oxygen atoms that interact with a current conducting filament;
a second metal oxide layer formed on the first metal oxide layer, the second metal oxide layer configured to form conduction paths; and
a second electrode formed on the second metal oxide layer, wherein the first metal oxide layer includes tungsten oxide (WO_{y}), and the second metal oxide layer includes hafnium oxide (HfOₓ) that is independent of thickness and composition of the WO_{y}.

12. The RRAM of claim 11, wherein x is greater than 1.0±0.1 and less than 2.0±0.1.

13. The RRAM of claim 11, where y is greater than 1.0±0.1 and less than 3.0±0.1.

14. The RRAM of claim 11, wherein x is greater than 1.0±0.1 and less than 2.0±0.1, and y is greater than 1.0±0.1 and less than 3.0±0.1.

15. The RRAM of claim 11, wherein the first metal oxide layer is formed on a portion of the first electrode.

16. The RRAM of claim 11, further comprising:
an electrical contact formed on the second electrode.

17. The RRAM of claim 16, wherein the electrical contact is formed on a portion of the second electrode.

18. The RRAM of claim 16, further comprising:
an additional electrical contact that electrically connects the first electrode through a via that penetrates the first metal oxide layer.

19. The RRAM of claim 11, wherein the first metal oxide layer has a capability of either absorbing or releasing oxygen atoms interacting with oxygen vacancy based current conducting filaments in the second metal oxide layer.

20. The RRAM of claim 11, wherein the second metal oxide layer has a capability of forming current conducting filaments during an electro-forming process.
